(19) United States
(12) Patent Application Publication
(10) Pub. No.: US 2024/0175121 A1
(43) Pub. Date: May 30, 2024

(54) FILM FORMING METHOD, PROCESSING APPARATUS, AND PROCESSING SYSTEM

(71) Applicant: Tokyo Electron Limited, Minato-ku, Tokyo (JP)

(72) Inventors: Munehito KAGAYA, Nirasaki City, Yamanashi (JP); Hiroki MURAKAMI, Nirasaki City, Yamanashi (JP)

(21) Appl. No.: 18/547,888

(22) PCT Filed: Feb. 16, 2022
(86) PCT No.: PCT/JP2022/006141

§ 371 Date: Aug. 25, 2023

(30) Foreign Application Priority Data
Mar. 2, 2021 (JP) 2021-032639

(51) Int. Cl. C23C 16/04; C23C 16/34; C23C 16/56; H01L 21/02; H01L 21/311; H01L 21/67

(52) U.S. Cl. CPC C23C 16/045; C23C 16/345; C23C 16/56; H01L 21/0217; H01L 21/02274; H01L 21/0228; H01L 21/31116; H01L 21/67069; H01L 21/67167

(57) ABSTRACT

An aspect of the present disclosure provides a film forming method of embedding a film in a recess that is formed in a substrate and has a narrow portion, the method comprising: an operation (a) of forming the film in the recess under a condition that the film is formed thicker at an opening than at a bottom portion of the recess; an operation (b) of forming the film in the recess under a condition that the film is formed with a same thickness at both the bottom portion of the recess and the opening of the recess, or a condition that the film is formed thicker at the bottom portion of the recess than at the opening of the recess; and an operation (c) of partially etching the film formed in the recess, wherein multiple cycles, each of which including the operation (b) and the operation (c), are performed

### TECHNICAL FIELD

The present disclosure relates to a film forming method, a processing apparatus, and a processing system.

### BACKGROUND

In semiconductor manufacturing processes, along with miniaturization of structures, a film needs to be embedded in a recess having a high aspect ratio without voids (gaps). As one example of a process of embedding a film in a recess, there is known a technique for embedding a film from the bottom portion of the recess in a bottom-up manner by alternately repeating deposition and etching (see, e.g., Patent Document 1).

### PRIOR ART DOCUMENT

### Patent Document

Patent Document 1: Japanese Laid-Open Patent Publication No. 2014-112668

The present disclosure provides a technique capable of preventing the generation of voids when embedding a film in recess having a narrow portion.

### SUMMARY

An aspect of the present disclosure provides a film forming method of embedding a film in a recess that is formed in a substrate and has a narrow portion, the film forming method comprising: an operation (a) of forming the film in the recess under a condition that the film is formed thicker at an opening of the recess than at a bottom portion of the recess; an operation (b) of forming the film in the recess under a condition that the film is formed with a same thickness at both the bottom portion of the recess and the opening of the recess, or a condition that the film is formed thicker at the bottom portion of the recess than at the opening of the recess; and an operation (c) of partially etching the film formed in the recess, wherein multiple cycles, each of which includes the operation (b) and the operation (c), are performed.

According to the present disclosure, it is possible to prevent the generation of voids when embedding a film in a recess having a narrow portion.

### BRIEF DESCRIPTION OF DRAWINGS

FIG. 1 is a flowchart illustrating an example of a film forming method according to an embodiment.

FIG. 2A is a cross-sectional process view illustrating the example of the film forming method according to the embodiment.

FIG. 2B is a cross-sectional process view illustrating the example of the film forming method according to the embodiment.

FIG. 2C is a cross-sectional process view illustrating the example of the film forming method according to the embodiment.

FIG. 2D is a cross-sectional process view illustrating the example of the film forming method according to the embodiment.

FIG. 2E is a cross-sectional process view illustrating the example of the film forming method according to the embodiment.

FIG. 2F is a cross-sectional process view illustrating the example of the film forming method according to the embodiment.

FIG. 3 is a view illustrating an example of a processing system for performing the film forming method according to the embodiment.

FIG. 4 is a view illustrating an example of a processing apparatus for performing the film forming method according to the embodiment.

FIG. 5 is a view (1) illustrating the result of forming a SiN film in a recess under a low coverage condition.

FIG. 6A is a view (2) illustrating the result of forming the SiN film in the recess under the low coverage condition.

FIG. 6B is a view (2) illustrating the result of forming the SiN film in the recess under the low coverage condition.

FIG. 7A is a view illustrating embedding characteristics when embedding a film in a recess having a narrow portion by a film forming method in the related art.

FIG. 7B is a view illustrating embedding characteristics when embedding the film in the recess having the narrow portion by the film forming method in the related art.

FIG. 7C is a view illustrating embedding characteristics when embedding the film in the recess having the narrow portion by the film forming method in the related art.

### DETAILED DESCRIPTION

Hereinafter, non-limitative exemplary embodiments of the present disclosure will now be described with reference to the accompanying drawings. In all the accompanying drawings, the same or corresponding members or components will be denoted by the same or corresponding reference numerals, and redundant explanations thereof will be omitted.

### [Embedding Process]

In semiconductor manufacturing processes, along with miniaturization of structures, a film needs to be embedded in a recess having a high aspect ratio without voids (gaps). As one example of a process of embedding a film in a recess, there is known a technique for embedding the film from the bottom portion of the recess in a bottom-up manner by alternately repeating deposition and etching (hereinafter also referred to as “DED process”). By using the DED process, the generation of voids can be prevented.

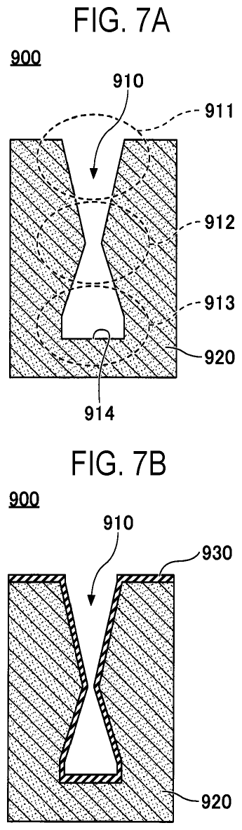

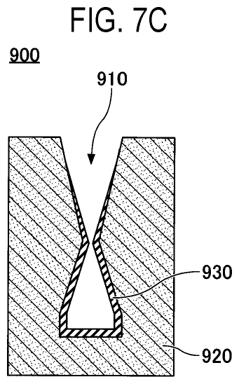

However, when the DED process is used to embed the film in a recess formed in a substrate and having a narrow portion, an opening of the recess may cause damage to a base. The reasons why the opening may cause damage to the base will be described with reference to FIGS. 7A to 7C. FIGS. 7A to 7C are views for explaining embedding characteristics when embedding a film in a recess having a narrow portion by a film forming method in the related art.

FIG. 7A is a schematic cross-sectional view of a substrate in which the recess having a narrow portion is formed. As illustrated in FIG. 7A, a substrate 900 includes a base 920 in which a recess 910 is formed. The recess 910 includes an opening 911, a narrow portion 912, and a bottom portion 913. The opening 911 is open at the top of the recess 910. The narrow portion 912 is formed between the opening 911 and the bottom portion 913 and has a smaller width than the opening 911 and the bottom portion 913 in a cross-sectional view. The bottom portion 913 is a portion including a bottom surface 914 of the recess 910 in a lower portion of the recess 910.

FIG. 7B is a schematic cross-sectional view of the substrate when a film is formed in conformity to the recess illustrated in FIG. 7A, which illustrates a state after deposition in the DED process. As illustrated in FIG. 7B, a film 930 is formed in conformity to the recess 910 of the substrate 900 such an extent so as not to block the narrow portion 912.

FIG. 7C is a schematic cross-sectional view of the substrate after performing dry etching with respect to the substrate having the film formed in conformity to the recess, which illustrates a state after etching in the DED process. As illustrated in FIG. 7C, in the substrate 900 in which the recess 910 having the narrow portion 912 is formed, the film 930 deposited at the narrow portion 912 may be preferably etched away to ensure that the film 930 is embedded in the bottom portion 913 by deposition after etching. Meanwhile, in the etching of the DED process, the film 930 formed in conformity to the recess 910 is etched to have a V shape in a cross-sectional view. That is, the etching is performed under a condition that an etching rate to the film 930 is higher at the opening 911 than at the bottom portion 913. Therefore, the film 930 deposited at the opening 911 is removed before removing the film 930 deposited at the narrow portion 912. Then, when the dry etching is continuously performed after the removal of the film 930 deposited at the opening 911, damage to the base 920, such as partial cutting of the base 920, may be caused. This is because the selectivity to the base is not infinite.

Hereinafter, a film forming method according to an embodiment, which is capable of embedding a film in a recess having a narrow portion without voids while suppressing damage to a base, will be described.

### [Film Forming Method]

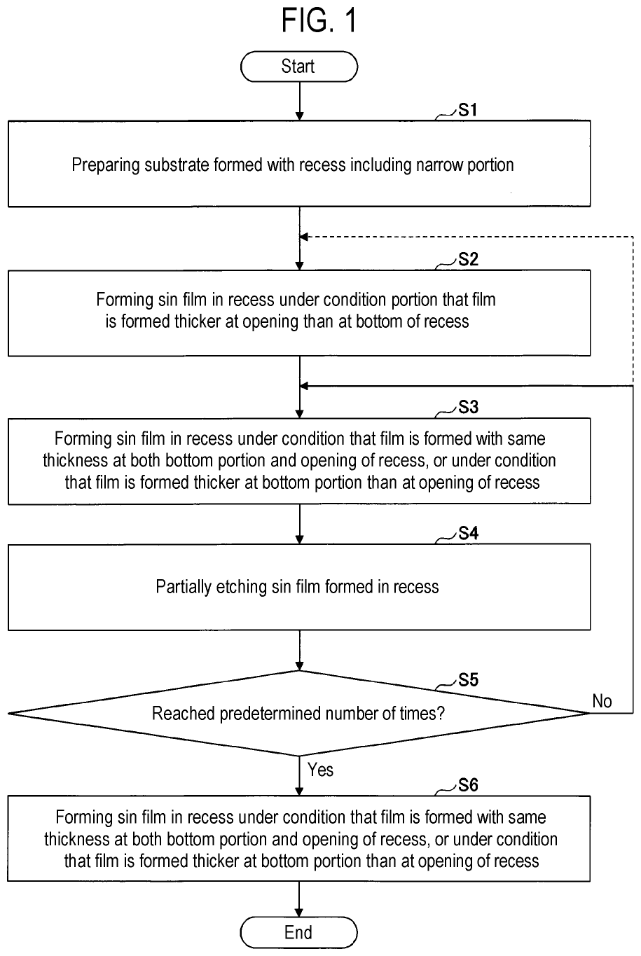

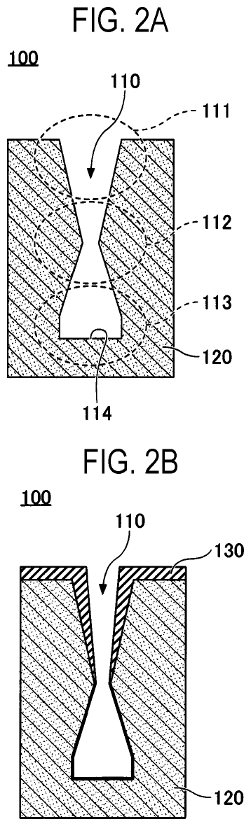

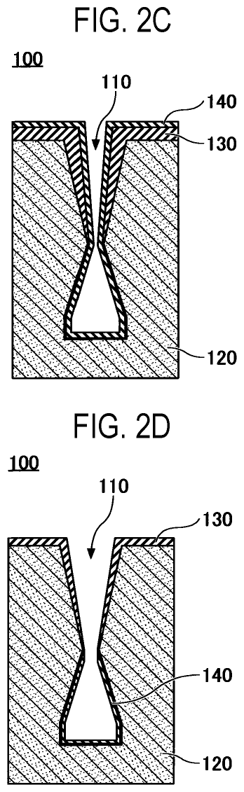

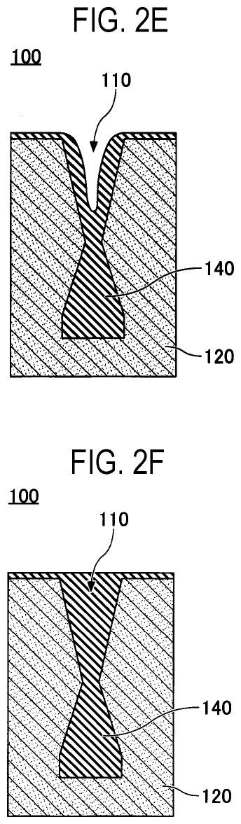

An example of the film forming method according to an embodiment will be described with reference to FIG. 1 and FIGS. 2A to 2F. In the following, a case where a silicon nitride film (SiN film) is formed and embedded in a recess will be described by way of example.

### (Operation S1)

First, in Operation S1, a substrate in which a recess having a narrow portion is formed is prepared. As illustrated in FIG. 2A, a substrate 100 includes a base 120 in which a recess 110 is formed. The recess 110 includes an opening 111, a narrow portion 112, and a bottom portion 113. The opening 111 is open at the top of the recess 110. The narrow portion 112 is formed between the opening 111 and the bottom portion 113 and has a smaller width than the opening 111 and the bottom portion 113 in a cross-sectional view. The bottom portion 113 is a portion including a bottom surface 114 of the recess 110 in a lower portion of the recess 110. In the illustrated example, the recess 110 has a shape that gradually narrows from the opening 111 toward the narrow portion 112, and gradually widens from the narrow portion 112 toward the bottom portion 113. However, the recess 110 is not limited to the illustrated shape, and may have another shape as long as it includes the narrow portion 112 provided between the opening 111 and the bottom portion 113. The recess 110 may be a trench, hole, or the like. The base 120 may be made of, for example, silicon or an insulating film, and may partially contain a metal or a metal compound.

### (Operation S2)

Next, in Operation S2, as illustrated in FIG. 2B, a SiN film 130 is formed in the recess 110 under a condition that the SiN film 130 is formed thicker at the opening 111 than at the bottom portion 113 of the recess 110 (hereinafter also referred to as “low coverage condition”).

Operation S2 may include forming the SiN film 130 by, for example, atomic layer deposition (ALD).

When forming the SiN film 130 by ALD, a step of supplying a silicon-containing gas to the substrate 100 and a step of exposing the substrate 100 to a plasma generated from a N₂-containing gas may be repeated in an alternate manner. In the step of supplying the silicon-containing gas to the substrate 100, the silicon-containing gas is adsorbed onto the substrate 100, and in the step of exposing the substrate 100 to the plasma generated from the N₂-containing gas, the silicon-containing gas adsorbed onto the substrate 100 is nitrided to form a SiN layer. Here, radicals in the plasma generated from the N₂-containing gas are less likely to reach the bottom portion 113 of the recess 110 due to a short lifetime thereof. Accordingly, the SiN film 130 is formed thinner at the bottom portion 113 of the recess 110. As a result, the SiN film 130 may be formed further thicker at the opening 111 than at the bottom portion 113 of the recess 110. In addition, the N₂-containing gas may contain N₂ alone, or may additionally contain NH₃ and H₂. In terms of a significant difference in film thickness between the bottom portion 113 and the opening 111, the N₂-containing gas may be N₂ alone.

Further, when forming the SiN film 130 by ALD, a step of supplying a silicon-containing gas to the substrate 100 in a supply rate-limitation mode and a step of supplying a nitrogen-containing gas to the substrate 100 may be repeated in an alternate manner. The supply rate-limitation mode refers to a mode in which a film formation rate is mainly controlled by a supply amount of processing gas in a region where the supply amount of processing gas supplied into a processing container in which the substrate 100 is accommodated is very low. For example, the supply rate-limitation mode may be implemented by reducing the supply amount of processing gas and increasing a processing temperature. By supplying the silicon-containing gas to the substrate 100 in the supply rate-limitation mode, the silicon-containing gas supplied to the recess 110 is adsorbed and consumed at the opening 111 or the narrow portion 112 before reaching the bottom portion 113. As a result, the SiN film 130 can be formed further thicker at the opening 111 than at the bottom portion 113 of the recess 110. In addition, the gas supplied to the substrate 100 in the supply rate-limitation mode is not limited to the silicon-containing gas, but may be a nitrogen-containing gas, or may be both the silicon-containing gas and the nitrogen-containing gas.

Further, when forming the SiN film 130 by ALD, a process of forming the SiN film 130 may be provided, and a process of etching the SiN film 130 may further be provided. The process of forming the SiN film 130 includes repeating a cycle including a step of supplying a silicon-containing gas to the substrate 100 and a step of supplying a nitrogen-containing gas to the substrate 100, and may further include a step of exposing the substrate 100 to plasma generated from a He-containing gas. In the step of supplying the silicon-containing gas to the substrate 100, the silicon-containing gas is adsorbed onto the substrate 100, while in the step of supplying the nitrogen-containing gas to the substrate 100, the silicon-containing gas adsorbed onto the substrate 100 is nitrided to form a SiN layer. Further, in the step of exposing the substrate 100 to the plasma generated from the He-containing gas, the SiN layer and/or the SiN film 130 are modified to have higher etching resistance. Here, in the modification by the plasma generated from the He-containing gas, the opening 111 of the recess 110 is more likely to be modified to have higher etching resistance than the bottom portion 113. Therefore, in the process of etching the SiN film 130 performed after the process of forming the SiN film 130, a larger amount of etching of the SiN film 130 occurs at the bottom portion 113 of the recess 110 than at the opening 111. As a result, the SiN film 130 can be formed further thicker at the opening 111 than at the bottom portion 113 of the recess 110. Further, the step of supplying the nitrogen-containing gas to the substrate 100 may be replaced with a step of exposing the substrate 100 to plasma generated from the nitrogen-containing gas. Further, the He-containing gas may contain, for example, Ar. Further, the process of etching the SiN film 130 may be either dry etching or wet etching. When etching the SiN film 130 by the dry etching, gases such as NF₃ and CHF-based gases may be used as an etching gas. Further, O₂, N₂, H₂, or the like may be added to such etching gases. When etching the SiN film 130 by the wet etching, diluted HF (DHF) or the like may be used as the etching gas.

Further, Operation S2 may include forming the SiN film 130 by chemical vapor deposition (CVD). By forming the SiN film 130 by CVD, the SiN film 130 can be formed thicker at the opening 111 than at the bottom portion 113 of the recess 110.

When forming the SiN film 130 by CVD, forming the SiN film 130 by thermal CVD (Th-CVD) in which a reaction between a silicon-containing gas and a nitrogen-containing gas occurs through heat, may be provided. In other words, supplying the silicon-containing gas and the nitrogen-containing gas to the substrate 100 to form the SiN film 130 may be provided.

Further, when forming the SiN film 130 by CVD, forming the SiN film 130 by plasma enhanced CVD (PE-CVD) in which a reaction between a silicon-containing gas and a nitrogen-containing gas is assisted by plasma, may be provided. In other words, exposing the substrate 100 to plasma generated from the silicon-containing gas and the nitrogen-containing gas to form the SiN film 130 may be provided.

Further, when forming the SiN film 130 by CVD, the silicon-containing gas and the nitrogen-containing gas may be supplied to the substrate 100 in a supply rate-limitation mode. By supplying the silicon-containing gas and the nitrogen-containing gas to the substrate 100 in the supply rate-limitation mode, the silicon-containing gas and the nitrogen-containing gas supplied to the recess 110 are consumed at the opening 111 or the narrow portion 112 before reaching the bottom portion 113. As a result, the SiN film 130 can be formed further thicker at the opening 111 than at the bottom portion 113 of the recess 110.

In addition, examples of the silicon-containing gas used in Operation S2 may include one or two or more gases selected from the group consisting of hexachlorodisilane (HCD), monosilane [SiH₄], disilane [Si₂H₆], dichlorosilane (DCS), hexaethylaminodisilane, hexamethyldisilazane (HMDS), tetrachlorosilane (TCS), disilylanine (DSA), trisilylamine (TSA) and bisteributylaminosilane (BTBAS), butylaminosilane, dimethylaminosilane, bisdimethylaminosilane, tridimethylaminesilane, diethylaminosilane, bisdiethylaminosilane, dipropylaminosilane, diisopropylaminosilane, hexakisethylaminodisilane, and the like.

Further, examples of the nitrogen-containing gas used in Operation S2 may include one or two or more gases selected from the group consisting of organic hydrazine compounds such as nitrogen (N₂), ammonia (NH₃), diazene (N₂H2), hydrazine (N₂H₄), monomethylhydrazine (CH3(NH)NH₂), and the like.

### (Operation S3)

Next, in Operation S3, as illustrated in FIG. 2C, a SiN film 140 is formed in the recess 110 under a condition that the SiN film 140 is formed with the same thickness at both the bottom portion 113 and the opening 111 of the recess 110, or is formed thicker at the bottom portion 113 than at the opening 111 of the recess 110.

Operation S3 may include forming the SiN film 140 by, for example, ALD. By forming the SiN film 140 using ALD, the SiN film 140 can be formed at the same thickness (in a conformal fashion) at both the bottom portion 113 and the opening 111 of the recess 110.

When forming the SiN film 140 by ALD, forming the SiN film 140 by thermal ALD (Th-ALD) in which a reaction between a silicon-containing gas and a nitrogen-containing gas occurs through heat, may be provided. In other words, alternately repeating a step of supplying the silicon-containing gas to the substrate 100 and a step of supplying the nitrogen-containing gas to the substrate 100 to form the SiN film 140 may be provided. In the step of supplying the silicon-containing gas to the substrate 100, the silicon-containing gas is adsorbed onto the substrate 100, while in the step of supplying the nitrogen-containing gas to the substrate 100, the silicon-containing gas adsorbed onto the substrate 100 is nitrided to form a SiN layer. Examples of the nitrogen-containing gas used in thermal ALD may include NH₃, N₂H₄, and the like.

Further, when forming the SiN film 140 by ALD, forming the SiN film 140 by plasma enhanced ALD (PE-ALD) in which a reaction between a silicon-containing gas and a nitrogen-containing gas is assisted by plasma, may be provided. In other words, alternately repeating a step of supplying the silicon-containing gas to the substrate 100 and a step of exposing the substrate 100 to plasma generated from a gas including the nitrogen-containing gas may be provided. Examples of the nitrogen-containing gas used in plasma enhanced ALD may include one or two or more gases selected from the group consisting of NH₃, N₂/H₂, and NH₃/N₂/H₂. A noble gas may be added to the nitrogen-containing gas.

Further, when forming the SiN film 140 by ALD, the SiN layer and/or the SiN film 140 may be modified to have high etching resistance by exposing the substrate 100 to plasma generated from a modification gas. That is, repeating a step of supplying the silicon-containing gas to the substrate 100, a step of exposing the substrate 100 to plasma generated from the gas including the nitrogen-containing gas, and a step of exposing the substrate 100 to the plasma generated from the modification gas may be provided. Example of the modification gas may include He, H₂, and the like.

Further, Operation S3 may include a step of forming an inhibiting area that inhibits deposition of a SiN film at the open side above the narrow portion 112 in the recess 110 (that is, at the side of the opening 111 that is shallower than the narrow portion 112). This inhibits the deposition of the SiN film 140 at the opening 111 of the recess 110, which makes it possible to form the SiN film 140 thicker at the bottom portion 113 than at the opening 111 of the recess 110. The step of forming the inhibiting area may include exposing the substrate 100 to plasma generated from, for example, a halogen-containing gas. Examples of the halogen-containing gas may include a fluorine gas (F₂), a chlorine gas (Cl₂), a hydrogen fluoride gas (HF), and the like. Further, the step of forming the inhibiting area may include exposing the substrate 100 to plasma generated from, for example, a N₂-containing gas.

In addition, the silicon-containing gas used in Operation S3 may be the same as the silicon-containing gas used in Operation S2. Examples of the silicon-containing gas may include silicon halide, aminosilane, and the like.

### (Operation S4)

Next, in Operation S4, as illustrated in FIG. 2D, the SiN films 130 and 140 formed in the recess 110 are etched under an etching condition that an etching rate at the opening 111 is higher than that at the bottom portion 113, so that the SiN films 130 and 140 are partially removed. Thus, the opening 111 and the narrow portion 112 widen, so that the SiN film 140 can be embedded at the side of the bottom portion 113 beyond the narrow portion 112 in Operation S3, which will be performed again later.

In Operation S4, since the etching of the SiN films 130 and 140 is performed under a condition that the etching rate of the SiN film 130 at the opening 111 is higher than that at the bottom portion 113, the etching amount of the SiN films 130 and 140 is greater at the opening 111 than at the narrow portion 112. Therefore, there is a concern that the SiN films 130 and 140 formed at the opening 111 may be removed before removing the SiN films 130 and 140 formed at the narrow portion 112, which exposes the base 120. However, in the present embodiment, the SiN film 130 is formed thicker at the opening 111 than at the bottom portion 113 of the recess 110 in Operation S2. This prevents the SiN films 130 and 140 formed at the opening 111 from being removed before removing the SiN films 130 and 140 formed at the narrow portion 112. Therefore, it is possible to prevent the exposure of the base 120 at the opening 111. As a result, even when the selectivity to the base is not infinite, it is possible to prevent damage to the base 120 at the opening 111.

Operation S4 may include supplying a NF₃ or CHF-based gas to the substrate 100. Thus, the SiN films 130 and 140 formed in the recess 110 can be etched under an etching condition that the etching rate at the opening 111 is higher than that at the bottom portion 113.

Further, Operation S4 may include supplying the NF₃ or CHF-based gas to the substrate 100 in a supply rate-limitation mode. Thus, the SiN films 130 and 140 formed in the recess 110 can be etched under an etching condition that the etching rate at the opening 111 is higher than that at the bottom portion 113.

### (Operation S5)

Next, in Operation S5, it is determined whether the number of repetitions of a cycle including Operation S3 and Operation S4 has been reached to a predetermined number of times. When the number of repetitions of the cycle including Operation S3 and Operation S4 has not been reached to the predetermined number of times, Operation S3 and Operation S4 are performed again. In other words, the film formation of the SiN film 140 in a conformal fashion or to be thinned at the opening 111, and the etching of the SiN films 130 and 140 are repeated until the number of repetitions reaches to the predetermined number of times. Thus, as illustrated in FIG. 2E, the SiN film 140 can be embedded without voids at the side of the bottom portion 113 of the recess 110 beyond the narrow portion 112. Further, when the number of repetitions of the cycle including Operation S3 and Operation S4 has been reached to the predetermined number of times, the process goes to Operation S6. The predetermined number of times is once or more.

Further, in a case where the SiN film 130 formed at the opening 111 is removed and the base 120 is exposed in Operation S4, or a case where the base 120 is likely to be exposed in Operation S4, Operation S2 may be performed after Operation S4 and before Operation S3 while Operation S3 and Operation S4 being repeated. In other words, some of multiple cycles, each including Operation S3 and Operation S4, may include Operation S2.

### (Operation S6)

Next, in Operation S6, the SiN film 140 is formed in the recess 110 under a condition that the SiN film 140 is formed with the same thickness at both the bottom portion 113 and the opening 111 of the recess 110, or under a condition that the SiN film 140 is formed thicker at the bottom portion 113 than at the opening 111 of the recess 110. Thus, as illustrated in FIG. 2F, the SiN film 140 can be embedded in the recess 110 without voids

Operation S6 may include forming the SiN film 140 by, for example, ALD. By forming the SiN film 140 using ALD, the SiN film 140 can be formed at the same thickness (in a conform fashion) at both the bottom portion 113 and the opening 111 of the recess 110. Further, by forming the SiN film 140 using ALD, the SiN film 140 may be formed thicker at the bottom portion 113 than at the opening 111 of the recess 110. The method of forming the SiN film 140 by ALD may be the same as the method of forming the SiN film 140 by ALD in Operation S3.

According to the above-described embodiment, by forming the SiN film under the low coverage condition on the substrate in which the recess having the narrow portion is formed, and subsequently repeating the film formation of the SiN film in a conformal fashion or to be thinned at the opening of the recess and the etching of the SiN film, the SiN film is embedded in the recess. Thus, the SiN film formed under the low coverage condition functions as a protective film to prevent the exposure of the base during the etching of the SiN film. This makes it possible to prevent damage to the base during the etching of the SiN film. Further, since the SiN film is formed in the recess by repeating the film formation of the SiN film n a conformal fashion or to be thinned at the opening, and the etching of the SiN film, blockage of the narrow portion can be prevented. As a result, it is possible to prevent the occurrence of voids when embedding the film in the recess.

### [Processing System]

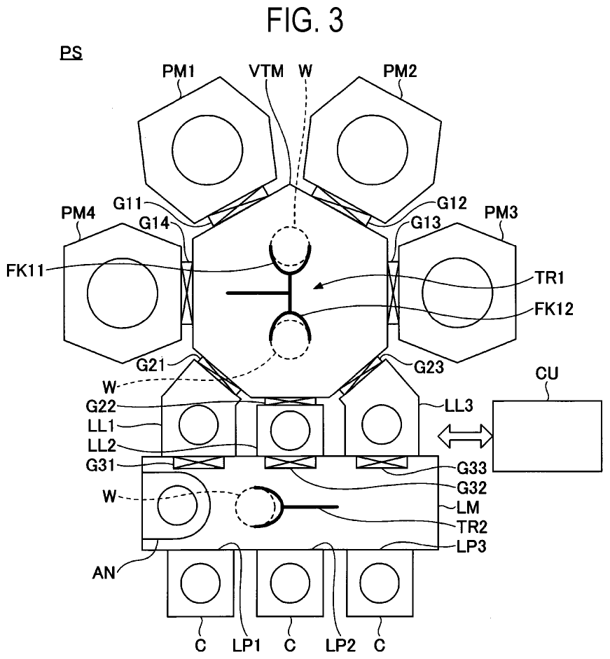

An example of a processing system for carrying out the film forming method according to the embodiment will be described with reference to FIG. 3.

A processing system PS includes processing apparatuses PM1 to PM4, a vacuum transfer chamber VTM, load-lock chambers LL1 to LL3, an atmospheric-side transfer chamber LM, load ports LP1 to LP3, and an overall controller CU0.

The processing apparatuses PM1 to PM4 are connected to the vacuum transfer chamber VTM via gate valves G11 to G14, respectively. The interiors of the processing apparatuses PM1 to PM4 are depressurized to a predetermined vacuum atmosphere, and a desired processing is performed on the substrate W in each of the interiors of the processing apparatuses PM1 to PM4.

The interior of the vacuum transfer chamber VTM is depressurized to a predetermined vacuum atmosphere. A transfer mechanism TR1 capable of transferring the substrate W in the depressurized state is provided in the vacuum transfer chamber VTM. The transfer mechanism TR1 transfers the substrate W to and from the processing apparatuses PM1 to PM4 and the load-lock chambers LL1 to LL3. The transfer mechanism TR1 includes, for example, two transfer arms FK11 and FK12, which are movable independently of each other.

The load-lock chambers LL1 to LL3 are connected to the vacuum transfer chamber VTM via gate valves G21 to G23, respectively, and are connected to the atmospheric-side transfer chamber LM via gate valves G31 to G33, respectively. The interiors of the load-lock chambers LL1 to LL3 are switchable between an ambient atmosphere and a vacuum atmosphere.

The atmospheric-side transfer chamber LM is in an ambient atmosphere. For example, a down-flow of clean air is established in the atmospheric-side transfer chamber LM. An aligner AN for performing the alignment of the substrate W is provided inside the atmospheric-side transfer chamber LM. Further, a transfer mechanism TR2 is provided inside the atmospheric-side transfer chamber LM. The transfer mechanism TR2 transfers the substrate W to and from the load-lock chambers LL1 to LL3, carriers C of the load ports LP1 to LP3 to be described later, and the aligner AN.

The load ports LP1 to LP3 are provided on a long-side wall surface of the atmospheric-side transfer chamber LM. The carriers C, which accommodate the substrate W therein or are empty, are installed in the load ports LP1 to LP3. For example, front opening unified pods (FOUPs) may be used as the carriers C.

The overall controller CU may be, for example, a computer. The overall controller CU includes a central processing unit (CPU), a random access memory (RAM), a read only memory (ROM), an auxiliary storage device, and the like. The CPU operates based on programs stored in the ROM or the auxiliary storage device to control each part of the processing system PS. For example, the overall controller CU executes operations such as the operation of the processing apparatuses PM1 to PM4, the operations of the transfer mechanisms TR1 and TR2, the opening and closing operations of the gate valves G11 to G14, G21 to G23, and G31 to G33, and the switching operations for the atmosphere in the lock lock chambers LL1 to LL3.

In the processing system PS according to the embodiment, at least one of the processing apparatuses PM1 to PM4 is used to consecutively perform Operations S2 to S4 and S6 of the film forming method according to the embodiment under a depressurized atmosphere. For example, one of the processing apparatuses PM1 to PM4 may be used to consecutively perform Operations S2 to S4 and S6. Further, for example, one of the processing apparatuses PM1 to PM4 may be used to consecutively perform Operations S2 and S3. Another apparatus may be used to perform Operation S4, and yet another apparatus may be used to perform Operation S6. Further, for example, the processing apparatuses PM1 to PM4 may be used to perform different Operations S2 to S4 and S6, respectively.

### [Processing Apparatus]

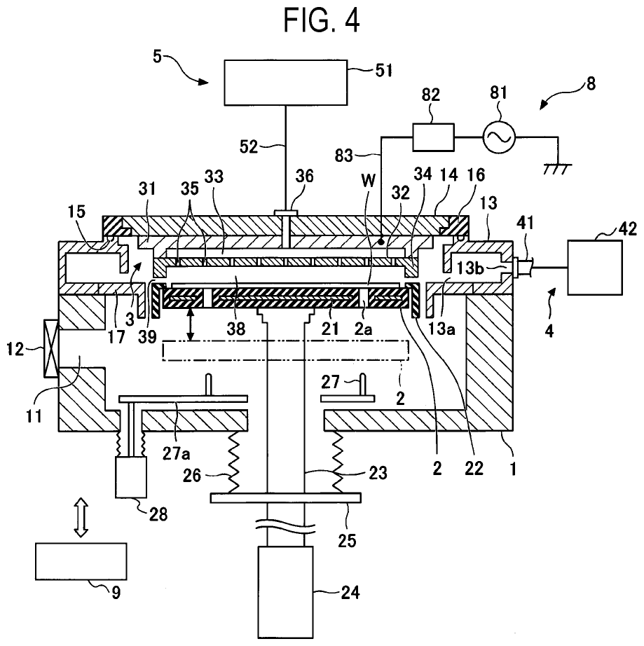

An example of a processing apparatus used as the processing apparatuses PM1 to PM4 included in the processing system PS of FIG. 3 will be described with reference to FIG. 4.

The processing apparatus includes a processing container 1, a stage 2, a shower head 3, an exhauster 4, a gas supplier 5, an RF power supplier 8, a controller 9, and the like.

The processing container 1 is made of a metal such as aluminum and has a substantially cylindrical shape. The processing container 1 accommodates the substrate W therein. The substrate W is, for example, a semiconductor wafer. A loading/unloading port 11 for loading or unloading the substrate W therethrough is formed in a sidewall of the processing container 1. The loading/unloading port 11 is opened or closed by a gate valve 12. An annular exhaust duct 13 having a rectangular cross section is provided on a main body of the processing container 1. A slit 13a is formed in the exhaust duct 13 along an inner peripheral surface thereof. An exhaust port 13b is formed in an outer wall of the exhaust duct 13. A ceiling wall 14 is provided on an upper surface of the exhaust duct 13 so as to close an upper opening of the processing container 1 with an insulator member 16 interposed therebetween. A space between the exhaust duct 13 and the insulator member 16 is airtightly sealed with a seal ring 15. A partitioning member 17 vertically partitions the interior of the processing container 1 when the stage 2 (and a cover member 22) has been raised to a processing position to be described later.

The stage 2 horizontally supports the substrate W inside the processing container 1. The stage 2 is formed in the shape of a disk having a size corresponding to the substrate W, and is supported by a support member 23. The stage 2 is made of a ceramic material such as AlN or a metal material such as an aluminum or nickel alloy, and includes a heater 21 embedded therein to heat the substrate W. The heater 21 generates heat with power supplied from a heater power supply (not illustrated). Then, the substrate W is controlled to a predetermined temperature by controlling an output of the heater 21 in response to a temperature signal of a thermocouple (not illustrated) provided near an upper surface of the stage 2. The cover member 22, which is made of ceramics such as alumina, is provided on the stage 2 so as to cover an outer peripheral region of the upper surface and a side surface of the stage 2.

The support member 23 is provided on a bottom surface of the stage 2 to support the stage 2. The support member 23 passes through a hole formed in a bottom wall of the processing container 1 from the center of the bottom surface of the stage 2 to extend downward of the processing container 1, and is connected at a lower end thereof to a lifting mechanism 24. The lifting mechanism 24 raises and lowers the stage 2 via the support member 32 between the processing position illustrated in FIG. 1 and a transfer position at which the transfer of the substrate W is possible below the processing position, as indicated by a two-dot dashed line. A flange 25 is attached to the support member 23 at a position below the processing container 1. A bellows 26 is provided between a bottom surface of the processing container 1 and the flange 25. The bellows 26 isolates an internal atmosphere of the processing container 1 from ambient air, and is flexible with the vertical movement of the stage 2.

Three (only two of which are illustrated) wafer support pins 27 are provided near the bottom surface of the processing container 1 so as to protrude upward from a lifting plate 27a. The wafer support pins 27 are lifted by a lifting mechanism 28 provided below the processing container 1 via the lifting plate 27a. The wafer support pins 27 are inserted into through-holes 2a provided in the stage 2 which is at the transfer position, and are capable of moving upward and downward with respect to the upper surface of the stage 2. The substrate W is transferred between a transfer mechanism (not illustrated) and the stage 2 by raising or lowering the wafer support pins 27.

The shower head 3 supplies a processing gas in the form of a shower into the processing container 1. The shower head 3 is made of a metal, is provided so as to face the stage 2, and has approximately the same diameter as the stage 2. The shower head 3 includes a main body 31 and a shower plate 32. The main body 31 is fixed to the ceiling wall 14 of the processing container 1. The shower plate 32 is connected below the main body 31. A gas diffusion space 33 is defined between the main body 31 and the shower plate 32. A gas introduction hole 36 is provided in the gas diffusion space 33 so as to penetrate the center of the ceiling wall 14 of the processing container 1 and the main body 31. An annular protrusion 34 is formed on a peripheral edge portion of the shower plate 32 so as to protrude downward. A gas discharge hole 35 is formed in an inner flat portion of the annular protrusion 34. When the stage 2 is present at the processing position, a processing space 38 is defined between the stage 2 and the shower plate 32, and an upper surface of the cover member 22 and the annular protrusion 34 are close to each other to form an annular gap 39.

The exhauster 4 exhausts the interior of the processing container 1. The exhauster 4 includes an exhaust pipe 41 connected to the exhaust port 13b and an exhaust mechanism 42 connected to the exhaust pipe 41. The exhaust mechanism 42 includes a vacuum pump, a pressure control valve, and the like. During a processing, the gas inside the processing container 1 reaches the exhaust duct 13 via the slit 13a, and is exhausted from the exhaust duct 13 via the exhaust pipe 41 by the exhaust mechanism 42.

The gas supplier 5 supplies various processing gases to the shower head 3. The gas supplier 5 includes a gas source 51 and a gas line 52. The gas source 51 includes, for example, various processing gas sources, mass flow controllers, and valves (none of which are illustrated). Various processing gases include those used in the film forming method according to the embodiment as described above. These various gases are introduced into the gas diffusion space 33 from the gas source 51 via the gas line 52 and the gas introduction hole 36.

Further, the processing apparatus is a capacitively coupled plasma apparatus, the stage 2 functions as a lower electrode, and the shower head 3 functions as an upper electrode. The stage 2 is grounded via a condenser (not illustrated). However, for example, the stage 2 may be grounded without a condenser, or may be grounded via a circuit in which a condenser and a coil are combined. The shower head 3 is connected to the RF power supplier 8.

The RF power supplier 8 supplies radio frequency power (hereinafter also referred to as “RF power”) to the shower head 3. The RF power supplier 8 includes an RF power supply 81, a matcher 82, and a feed line 83. The RF power supply 81 is a power supply that generates RF power. The RF power has a frequency suitable for plasma generation. The frequency of RF power ranges, for example, from 450 KHz in a low frequency band to 2.45 GHz in a microwave band. The RF power supply 81 is connected to the main body 31 of the shower head 3 via the matcher 82 and the feed line 83. The matcher 82 includes a circuit for matching a load impedance to an internal impedance of the RF power supply 81. In addition, the RF power supplier 8 has been described as supplying the RF power to the shower head 3 serving as an upper electrode, but is not limited thereto. A configuration may be used in which the RF power is supplied to the stage 2 serving as a lower electrode.

The controller 9 is, for example, a computer, and includes a central processing unit (CPU), a random access memory (RAM), a read only memory (ROM), an auxiliary storage device, and the like. The CPU operates based on programs stored in the ROM or the auxiliary storage device, and controls the operation of the processing apparatus. The controller 9 may be provided inside or outside the processing apparatus. When the controller 9 is provided outside the processing apparatus, the controller 9 may control the processing apparatus by, for example, a communication means based on a wired or wireless manner.

### [Evaluation Results]

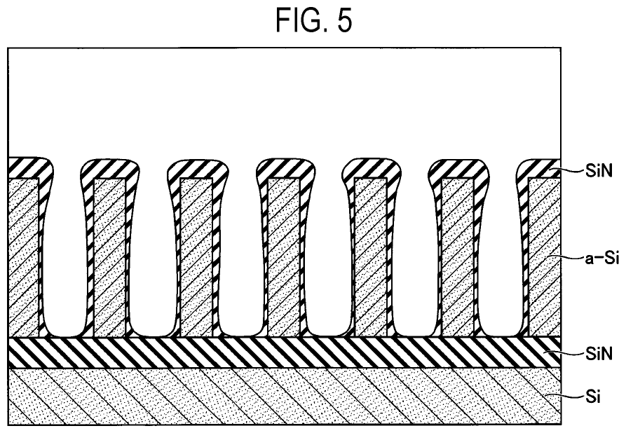

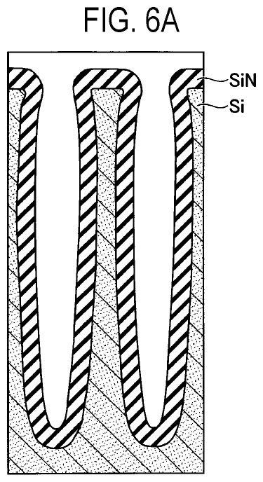

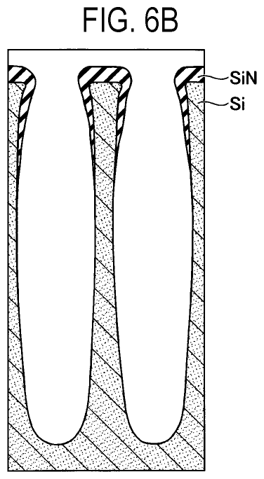

Referring to FIG. 5 and FIGS. 6A and 6B, the SiN film was formed in the recess (trench) under the low coverage condition used in Operation S2 of the film forming method according to the embodiment, and the formed SiN film was observed with an electron microscope.

First, a substrate including a recess formed by an amorphous silicon (a-Si) film on a SiN film was prepared. Next, a SiN film was formed in the recess under the low coverage condition by alternately repeating a step of supplying a silicon-containing gas to the substrate and a step of exposing the substrate to plasma generated from a N₂-containing gas. Bisdiethylaminosilane (BDEAS) was used as the silicon-containing gas. A mixed gas of N₂ and Ar was used as the N₂-containing gas. Specifically, in the processing apparatus as illustrated in FIG. 4, for example, the SiN film was formed in the recess, within a pressure range of 0.1 to 50 Torr (1.3×10¹ to 6.7×10³ Pa), by alternately repeating a step of supplying BDEAS at a specific flow rate for 0.05 to 1.0 seconds and a step of exposing the substrate to plasma with a power of 10 to 1,000 W, which is generated from a specific flow rate of N₂, for 0.1 to 6.0 seconds.

FIG. 5 is a view illustrating the result of forming the SiN film in the recess under the low overage condition, and shows the observed result with the scanning electron microscope (SEM).

As illustrated in FIG. 5, it can be seen that the SiN film is formed thicker at the opening than at the bottom portion of the recess. From this result, it has been demonstrated that, by alternately repeating the step of supplying the silicon-containing gas to the substrate and exposing the substrate to the plasma generated from the N₂-containing gas, it is possible to form the SiN film thicker at the opening than at the bottom portion of the recess.

Subsequently, a substrate including a recess, made of crystalline silicon (Si), was prepared. Then, a SiN film was formed in the recess under a low coverage condition by performing an operation of forming a SiN film and a process of etching the SiN film in this order. In the operation of forming the SiN film, a cycle including a step of supplying a silicon-containing gas to the substrate, a step of exposing the substrate to a plasma generated from a nitrogen-containing gas, and a step of exposing the substrate to a plasma generated from a He-containing gas was repeated. In the operation of etching the SiN film, wet etching using diluted hydrofluoric acid was performed. Dichlorosilane (DCS) was used as the silicon-containing gas. NH₃ was used as the nitrogen-containing gas. A mixed gas of He and Ar was used as the He-containing gas. Specifically, in the processing apparatus as illustrated in FIG. 4, for example, the SiN film was formed in the recess, within a pressure range of 0.1 to 50 Torr (1.3×10¹ to 6.7×10³ Pa), by repeating a step of supplying DCS at a specific flow rate for 0.05 to 1.0 seconds, a step of exposing the substrate to plasma with a power of 100 to 3,000 W, generated from a specific flow rate of NH₃, for 1.0 to 10.0 seconds, and a step of exposing the substrate to plasma with a power of 10 to 1,000 W, generated from a specific flow rate of He, for 1.0 to 10.0 seconds.

FIGS. 6A and 6B are views illustrating the result of forming a SiN film in a recess under a low coverage condition, and shows the observed result with a transmission electron microscope (TEM). FIG. 6A shows the observed result with the TEM after the operation of forming the SiN film, and FIG. 6B shows the observed result with the TEM after the operation of etching the SiN film.

As illustrated in FIG. 6A, it can be seen that a SiN film is formed in conformity to a recess after the operation of forming the SiN film. Further, as illustrated in FIG. 6B, it can be seen that, after the operation of etching the SiN film, the SiN film formed at the bottom portion of the recess is mostly removed, while the SiN film formed at the opening of the recess remains. From these results, it has been demonstrated that it is possible to form the SiN film thicker at the opening than at the bottom portion of the recess by exposing the substrate to the plasma generated from the He-containing gas during the operation of forming the SiN film, followed by etching the SiN film formed in the operation of forming the SiN film.

It should be noted that the embodiments disclosed herein are exemplary in all respects and are not restrictive. The above-described embodiments may be omitted, replaced or modified in various forms without departing from the scope and spirit of the appended claims.

In the above-described embodiment, the processing apparatus has been described as a capacitively coupled plasma apparatus, but the present disclosure is not limited thereto. For example, the processing apparatus may be a plasma apparatus that uses any other plasma source such as inductively coupled plasma, surface wave plasma (microwave plasma), magnetron plasma, remote plasma or the like.

In the above-described embodiment, the case where the SiN film is embedded in the recess has been described as an example of the film forming method, but the present disclosure is not limited thereto. For example, the film embedded in the recess may be a silicon oxide film (SiO₂ film), a metal nitride film, or a metal oxide film.

In the above-described embodiment, the case where the processing apparatus is a single wafer type apparatus that processes wafers one by one has been described, but the present disclosure is not limited thereto. For example, the processing apparatus may be a batch type apparatus that processes a plurality of wafers at once. Further, for example, the processing apparatus may be a semi-batch type apparatus that revolves a plurality of wafers, disposed on a turntable inside a processing container, by the turntable, and sequentially passes the wafers through a region to which a first gas is supplied and a region to which a second gas is supplied to perform processing on the wafers. Further, a multi-wafer type processing apparatus including a plurality of stages provided inside one processing container may be used as the processing apparatus.

### INDUSTRIAL USE OF THE PRESENT DISCLOSURE

This international application claims priority based on Japanese Patent Application No. 2021-032639 filed on Mar. 2, 2021, and the entire content of that application is incorporated herein in its entirety by reference of this international application.

### EXPLANATION OF REFERENCE NUMERALS

100: substrate, 110: recess, 111: opening, 112: narrow portion, 113: bottom portion, 130: SiN film, 140: SiN film

1-15: (canceled)

16. A film forming method of embedding a film in a recess that is formed in a substrate and has a narrow portion, the film forming method comprising:
an operation (a) of forming the film in the recess under a condition that the film is formed thicker at an opening of the recess than at a bottom portion of the recess;
an operation (b) of forming the film in the recess under a condition that the film is formed with a same thickness at both the bottom portion of the recess and the opening of the recess, or a condition that the film is formed thicker at the bottom portion of the recess than at the opening of the recess; and
an operation (c) of partially etching the film formed in the recess,
wherein multiple cycles, each of which includes the operation (b) and the operation (c), are performed.

17. The film forming method of claim 16, wherein at least some of the multiple cycles includes the operation (a).

18. The film forming method of claim 17, wherein the operation (a) includes forming the film by an atomic layer deposition (ALD).

19. The film forming method of claim 18, wherein the operation (a) includes alternately repeating supplying a silicon-containing gas to the substrate and exposing the substrate to a plasma generated from a gas containing N₂.

20. The film forming method of claim 18, wherein the operation (a) includes alternately repeating supplying a silicon-containing gas to the substrate and supplying a nitrogen-containing gas to the substrate, and
wherein either or both of the silicon-containing gas and the nitrogen-containing gas are supplied in a supply rate-limitation mode.

21. The film forming method of claim 18, wherein the operation (a) includes:
forming a silicon nitride film by repeating a cycle including supplying a silicon-containing gas to the substrate, supplying a nitrogen-containing gas to the substrate, and exposing the substrate to a plasma generated from a He-containing gas; and
etching the silicon nitride film.

22. The film forming method of claim 16, wherein the operation (a) includes forming the film by a chemical vapor deposition (CVD).

23. The film forming method of claim 22, wherein the operation (a) includes exposing the substrate to a plasma generated from a silicon-containing gas and a nitrogen-containing gas.

24. The film forming method of claim 23, wherein the operation (b) includes forming the film by an atomic layer deposition (ALD).

25. The film forming method of claim 24, wherein the operation (b) includes alternately repeating supplying a silicon-containing gas to the substrate and supplying a nitrogen-containing gas to the substrate, and
wherein the nitrogen-containing gas is NH₃, N₂/H₂, or NH₃/N₂/H₂.

26. The film forming method of claim 24, wherein the operation (b) includes forming an inhibiting area that inhibits deposition of the film on a side of the opening rather than the narrow portion of the recess.

27. The film forming method of claim 25, wherein the film is a silicon nitride film.

28. The film forming method of claim 27, wherein the operation (a), the operation (b), and the operation (c) are continuously performed under a depressurized atmosphere.

29. The film forming method of claim 16, wherein the operation (a) includes forming the film by an atomic layer deposition (ALD).

30. The film forming method of claim 29, wherein the operation (a) includes alternately repeating supplying a silicon-containing gas to the substrate and exposing the substrate to a plasma generated from a gas containing N₂.

31. The film forming method of claim 16, wherein the operation (b) includes forming the film by an atomic layer deposition (ALD).

32. The film forming method of claim 16, wherein the film is a silicon nitride film.

33. The film forming method of claim 16, wherein the operation (a), the operation (b), and the operation (c) are continuously performed under a depressurized atmosphere.

34. A processing apparatus for performing a film forming method of embedding a film in a recess that is formed in a substrate and has a narrow portion, comprising:
a processing container in which the substrate is accommodated;
a gas supplier configured to supply a processing gas into the processing container; and
a controller,
wherein the controller is configured to control the gas supplier so as to execute:
an operation (a) of forming the film in the recess under a condition that the film is formed thicker at an opening of the recess than at a bottom portion of the recess;
an operation (b) of forming the film in the recess under a condition that the film is formed with a same thickness at both the bottom portion of the recess and the opening of the recess, or a condition that the film is formed thicker at the bottom portion of the recess than at the opening of the recess; and
an operation (c) of partially etching the film formed in the recess, and
wherein the controller is configured to control the gas supplier so as to execute multiple cycles, each of the multiple cycles including the operation (b) and the operation (c).

35. A processing system for performing a film forming method of embedding a film in a recess that is formed in a substrate and has a narrow portion, comprising:
a first film-forming module configured to form the film in the recess under a condition that the film is formed thicker at an opening of the recess than at a bottom portion of the recess;
a second film-forming module configured to form the film in the recess under a condition that the film is formed with a same thickness at both the bottom portion and the opening of the recess, or a condition that the film is formed thicker at the bottom portion of the recess than at the opening of the recess;
an etching module configured to partially etch the film formed in the recess; and
a transfer module configured to transfer the substrate between the first film-forming module, the second film-forming module, and the etching module under a depressurized atmosphere.
